(19) United States
(12) Patent Application Publication
(10) Pub. No.: US 2013/0273670 A1
(43) Pub. Date: Oct. 17, 2013

(54) Concentration Measuring Device used in Manufacturing Process

(71) Applicant: HORIBA, LTD., Kyoto-shi (JP)

(72) Inventors: Kimihiko ARIMOTO, Kyoto-shi (JP); So TAKAGI, Kyoto-shi (JP)

(73) Assignee: HORIBA, Ltd., Kyoto-shi (JP)

(21) Appl. No.: 13/861,076

(22) Filed: Apr. 11, 2013

(30) Foreign Application Priority Data
Apr. 12, 2012 (JP) 2012-091034

(51) Int. Cl. G01N 21/85

(52) U.S. Cl. CPC G01N 21/85; H01L 22/26
USPC 438/5; 73/61.41; 250/576; 29/705

(57) ABSTRACT

A semiconductor manufacturing system comprises a main body that exclusively flows a first fluid that is used in a manufacturing process and a second fluid whose concentration is known, and that outputs a state signal showing whether or not the fluid flowing in the flow channel is the second fluid and a concentration measuring device having a concentration measuring part that measures a concentration of a predetermined component in the fluid flowing in the flow channel, a state signal receiving part that receives the state signal from the main body, and a correcting part that obtains a reference measurement value as being a measurement value measured by the concentration measuring part during a period while it is judged that the second fluid flows in the flow channel by the state signal and that corrects the concentration measuring part based on the reference measurement value.

### CROSS REFERENCE TO RELATED APPLICATIONS

The present invention claims priority under 35 U.S.C. §119 to Japanese Application No. 2012-091034 filed Apr. 12, 2012, the entire content of which is incorporated herein by reference.

### FIELD OF THE ART

This invention relates to a manufacturing process such as a semiconductor manufacturing system and a concentration measuring device that measures a concentration of a component such as cleaning(washing) chemicals used in the manufacturing process.

### BACKGROUND ART

Liquids such as cleaning chemicals that are used in a semiconductor manufacturing system require controlling of a concentration, and in order to control the concentration, the system is provided with a concentration measuring device in addition to a main body. Conventionally, as this kind of the concentration measuring device known is that the main body is provided with a cell on a flow channel where a liquid flows, light is irradiated on the cell and a concentration of a component of the liquid is measured based on the absorbance.

Meanwhile, in case of correcting this concentration measuring device, as shown in the patent document 1, the semiconductor manufacturing process is halted and a flow of the liquid is stopped, and then a reference sample (air in the patent document 1) whose concentration is known flows instead of the liquid and a concentration of the reference sample is measured so as to obtain a data for correction.

### PRIOR ART DOCUMENTS

### Patent Documents

Patent document 1: Japanese Unexamined Patent Application Publication No. 2005-274143

### DISCLOSURE OF THE INVENTION

### Problems to be Solved by the Invention

With the above-mentioned arrangement, however, a semiconductor manufacturing process has to be interrupted at a time of correction. In addition, it can be conceived that the cell is moved so as to be replaced by a cell for correction at a time of correction in order not to interrupt the semiconductor manufacturing process. However, with this arrangement, there will be problems that a measurement of a concentration of the liquid is interrupted while correction and a structure becomes complicated because a driving mechanism to move the cell is necessary.

The present claimed invention focuses attention on that the liquid does not always flow in the main body and there is a timing to flow the water to clean away the liquid. At least an embodiment of this invention provides a structurally feasible manufacturing process system and a concentration measuring device used for the manufacturing process system that can conduct a correction for measuring the concentration of the liquid periodically without interrupting a manufacturing process and that can measure the concentration without fail while the liquid flows.

### Means to Solve the Problems

More specifically, the concentration measuring device in accordance with this invention is used together with a main body that has a flow channel, that exclusively flows a first fluid used in a manufacturing process and a second fluid whose concentration is known and that is used in the manufacturing process in the flow channel, and that outputs a state signal showing whether or not the fluid flowing in the flow channel is the second fluid, and is characterized by comprising a concentration measuring part that measures a concentration of a predetermined component in the fluid flowing in the flow channel, a state signal receiving part that receives the state signal from the main body, and a correcting part that obtains a reference measurement value as being a measurement value measured by the concentration measuring part during a period while it is judged that the second fluid flows in the flow channel by the state signal and that corrects the concentration measuring part based on the reference measurement value.

In accordance with this arrangement, since the timing when the second fluid whose concentration is known flows is grasped by the concentration measuring device during the manufacturing process, the reference measurement value is obtained by making use of the second fluid at this timing, and the correction is conducted, it is possible to conduct the correction without interrupting the manufacturing process and to measure the concentration of the fluid without fail during the period while the first fluid whose concentration is required to be measured flows. In addition, since it is possible to use a fixed type as the cell, a driving mechanism becomes unnecessary so that the structure can be simplified.

The first fluid and the second fluid may be a fluid of the same kind, however, the concentration of the predetermined component to be measured in the second fluid has to be known. In addition, as the manufacturing process represented are a physical treatment process and a chemical treatment process such as, for example, a semiconductor manufacturing process, a solar cell manufacturing process, a liquid crystal manufacturing process and a plating process.

In case that the manufacturing process is, for example, a semiconductor manufacturing process, it can be represented that the main body flows the second fluid in the flow channel during at least either one of a semiconductor substrate cleaning period, a semiconductor substrate delivery period, a semiconductor substrate drying period and a waiting period.

As an embodiment wherein an effect of this invention is especially remarkable it is preferable that the main body comprises a mixing part that mixes introduced one or a plurality of undiluted solutions with the second fluid in a predetermined ratio so as to produce the first fluid and that flows the produced first fluid, and in case that the second fluid flows in the flow channel, the undiluted solution is halted to be introduced into the mixing part.

As the second fluid represented is a dilute solution such as water. In this case, since an absorbance of the second fluid can be assumed zero, the correcting part may conduct an offset compensation as the correction.

As a concrete embodiment of the concentration measuring device represented is a concentration measuring device that comprises a transparent cell arranged in the flow channel, a light source that irradiates light on the transparent cell, a light detecting part that receives the light having passed the transparent cell and that outputs a signal whose value depends on intensity of the received light and a concentration measuring part that calculates a concentration of the fluid by providing a predetermined calculation on the value of the detected signal of the light detecting part, wherein the correcting part provides a compensation on the calculation.

In addition, as a manufacture processing system that produces the same effect, the manufacture processing system in accordance with this invention is characterized by comprising a main body that has a flow channel, that exclusively flows a first fluid used in a manufacturing process and a second fluid whose concentration is known and that is used in the manufacturing process in the flow channel, and that outputs a state signal showing whether or not the fluid flowing in the flow channel is the second fluid, and a concentration measuring device having a concentration measuring part that measures a concentration of a predetermined component in the fluid flowing in the flow channel, a state signal receiving part that receives the state signal from the main body, and a correcting part that obtains a reference measurement value as being a measurement value measured by the concentration measuring part during a period while it is judged that the second fluid flows in the flow channel by a value of the state signal and that corrects the concentration measuring part based on the reference measurement value. The main body may judge whether or not the second fluid flows.

Furthermore, as a correcting method for the manufacture processing system that produces the same effect, the correcting method in accordance with this invention is characterized by that a first fluid used in a manufacturing process and a second fluid whose concentration is known and that is used in the manufacturing process flow exclusively in an identical flow channel, and a state signal that shows whether the fluid flowing in the flow channel is the second fluid or not is output, whether the second fluid flows in the flow channel or not is judged based on a value of the state signal, a concentration of the second fluid flowing in the flow channel is measured during a period while it is judged that the second fluid flows in the flow channel, and the concentration measurement is corrected based on a reference measurement value as being the measurement result

### Effect of the Invention

In accordance with this invention having the above-mentioned arrangement, since the timing when the second fluid whose concentration is known flows is grasped by the concentration measuring device during the manufacturing process, the reference measurement value is obtained by making use of the second fluid at this timing, and the correction is conducted, it is possible to conduct the correction without interrupting the manufacturing process and to measure the concentration of the fluid without fail during the period while the first fluid whose concentration is required to be measured flows. In addition, since it is possible to use a fixed type as the cell, a driving mechanism becomes unnecessary so that the structure can be simplified.

### BRIEF DESCRIPTION OF THE DRAWINGS

FIG. 1 is a pattern overall view showing an outline of a semiconductor manufacturing system in accordance with one embodiment of this invention.

FIG. 2 is a timing chart showing a timing when a dilute solution and a cleaning chemical flow and a timing when a state signal is output in this embodiment

### BEST MODES OF EMBODYING THE INVENTION

A concentration measuring device in accordance with this embodiment will be explained with reference to drawings.

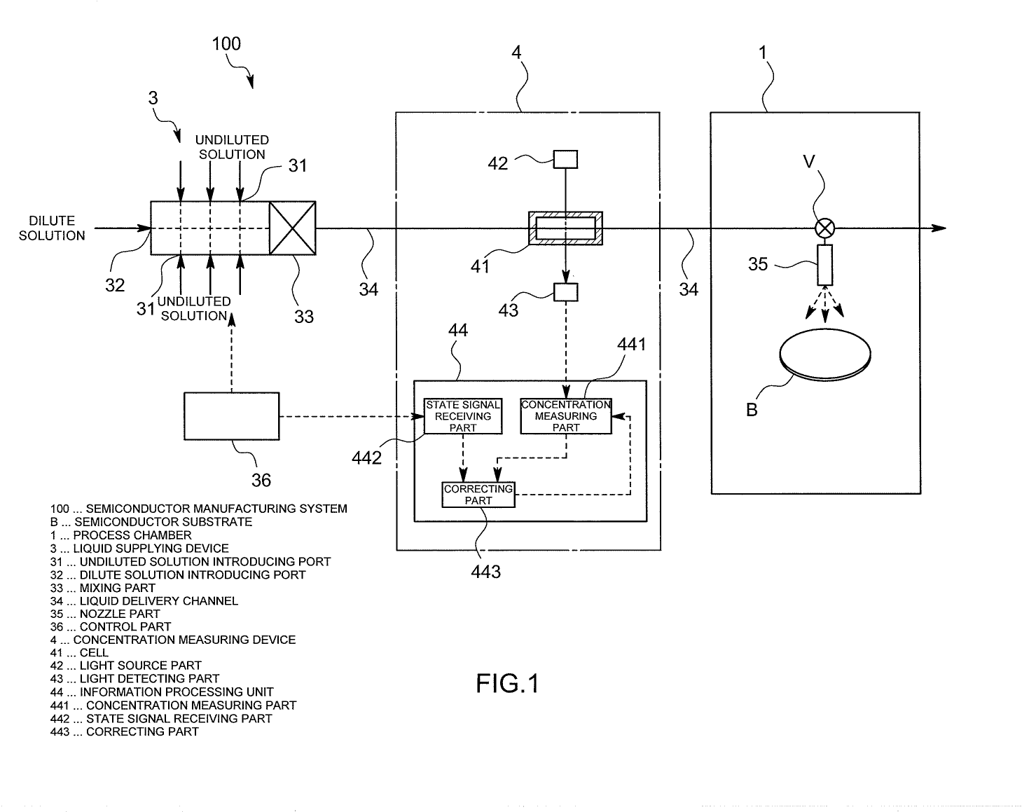

FIG. 1 is a pattern diagram showing a semiconductor manufacturing system 100 in accordance with this embodiment. In this embodiment the semiconductor manufacturing system 100 is used for a cleaning process. The semiconductor manufacturing system 100 is of so-called a single wafer type wherein a semiconductor substrate (B) like a wafer is delivered one by one to a process chamber 1 and provided with the cleaning process.

The cleaning process includes a process of applying the cleaning chemical as being a first fluid in claims to the semiconductor substrate (B) and a process of drying the semiconductor substrate (B). In order to conduct these processes, as shown in FIG. 1, the semiconductor manufacturing system 100 is provided with a delivery device, not shown in drawings, that delivers the semiconductor substrate (B), a liquid supplying device 3 as being a main body that sprays the cleaning chemical to the semiconductor substrate (B) and a concentration measuring device 4 that measures a concentration of a component of the first fluid as being a measurement sample.

As shown in FIG. 1, the liquid supplying device 3 mixes multiple dissolved substances (undiluted solutions in this embodiment) and a solvent (a dilute solution in this embodiment) as being the second fluid so as to produce the cleaning chemical, and supplies the produced cleaning chemical to the semiconductor substrate (B). The liquid supplying device 3 has undiluted solution introducing ports 31 into which each undiluted solution is introduced, a dilute solution introducing port 32 into which the dilute solution is introduced, a mixing part 33 that mixes the undiluted solutions and the dilute solution that are introduced into inside of the liquid supplying device 3 so as to produce the cleaning chemical, a liquid delivery channel 34 as being a flow channel that sends out the cleaning chemical from the mixing part 33, a nozzle part 35 that is arranged on a distal end part of the liquid delivery channel 34 and that blows out the cleaning liquid to the semiconductor substrate (B) and a control part 36 that drives a valve, not shown in drawings, so as to control a flow rate of the undiluted solution and the dilute solution.

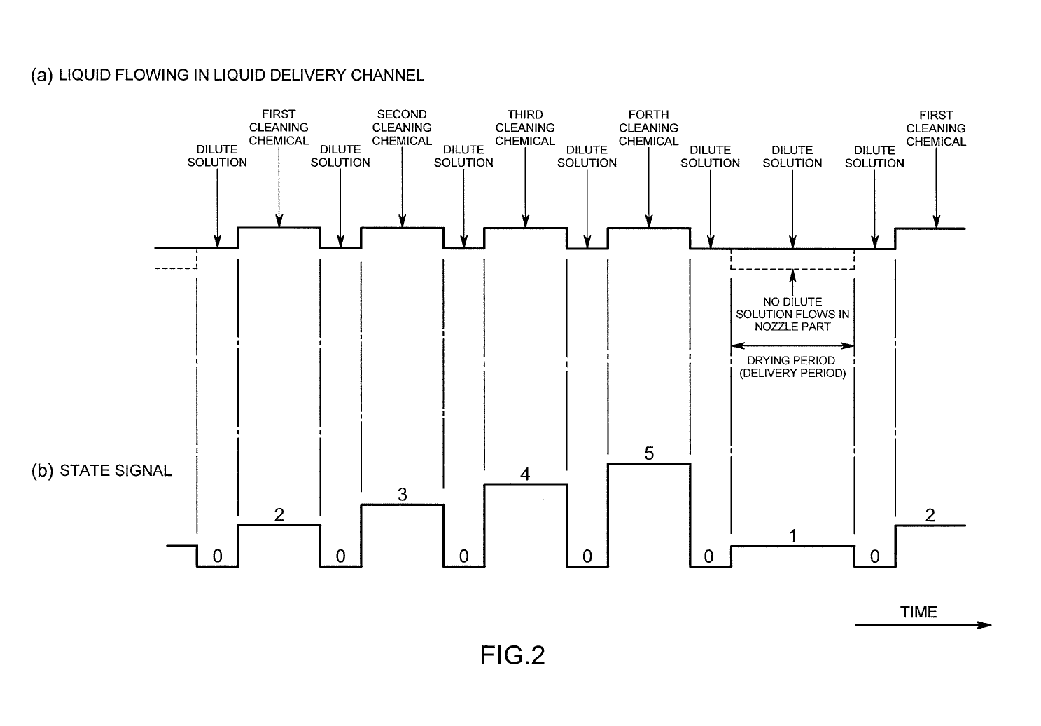

Then, the liquid supplying device 3 controls the flow rate of the undiluted solution and the flow rate of the dilute solution by means of a valve control by the control part 36, produces successively multiple kinds of cleaning chemicals whose component or concentration varies each other and conducts a cleaning process wherein the cleaning chemical is sprayed sequentially from the nozzle part 35 to the semiconductor substrate (B). On example will be shown in a timing chart of FIG. 2(a).

In this embodiment, the semiconductor substrate (B) is brought at a predetermined position, and a process of a unit is periodically repeated to different semiconductor substrate (B). The process of the unit includes processes that a first cleaning chemical, a second cleaning chemical, a third cleaning chemical and a forth cleaning chemical whose component varies each other are intermittently sprayed on the semiconductor substrate (B) in turn so as to clean the semiconductor substrate (B), and the semiconductor substrate (B) is dried for a certain period and then delivered out.

It is so configured that only the dilute solution flows as a purge liquid in the liquid delivery channel 34 due to a movement of the control part 36 during a drying period (a delivery period) of the semiconductor substrate (B) and a period between a spraying process of the cleaning chemical and a succeeding spraying process of the cleaning chemical. The dilute solution does not flow in the nozzle part 35 due to a switch valve (V) and is discharged through other path in the almost all of the drying period (the delivery period).

The concentration measuring device 4 comprises, as shown in FIG. 1, a transparent cell 41 arranged on the liquid delivery channel 34, a light source part 42 that irradiates predetermined measurement light (hereinafter also called as primary light) on the transparent cell 41, a light detecting part 43 that detects the intensity of the measurement light (hereinafter also called as secondary light) that has passed the cell 41, and an information processing unit 44 that receives the detected signal from the light detecting part 43 and that calculates a concentration of a component of each undiluted solution based on the received detected signal.

Each part will be described in detail. The transparent cell 41 is of a fixed type inside of which the liquid passes.

The light source part 42 irradiates the primary light having a broad spectrum such as a halogen lamp. The light source 42 may use LEDs or a laser.

The light detecting part 43 diffracts the secondary light that has passed the cell 41 and detects the light intensity of each wave length of the diffracted light. The light detecting part 43 comprises a diffracting device, not show in drawings, such as a diffraction grating and a multi-channel detecting device, not shown in drawings, to detect the light intensity of each wave length.

The information processing unit 44 comprises a CPU, a memory, an AD converter and an output device such as a display. The information processing unit 44 functions as a concentration measuring part 441 in cooperation with the CPU or its peripheral devices based on predetermined programs stored in the memory. The concentration measuring part 441 obtains an absorbance by conducting various calculations on a value of the detected signal received from the light detecting device 43 and calculates a concentration of a component of each undiluted solution in liquid based on the absorbance.

Meanwhile, if the intensity of the primary light changes with time, a window of the cell 41 gets tainted or a photoelectric conversion power of the light detecting part 43 changes with time, some error is observed in calculating the absorbance. As a result, in case of calculating the concentration, it is necessary to conduct a correction such as compensating a coefficient of an arithmetic expression.

Then in this embodiment, since the diluted solution is water and the water can be used as a reference liquid as being a reference for measurement, the information processing unit 44 automatically conducts a correction movement while the dilute solution flows.

Concretely, as shown in FIG. 2(b), the control part 36 outputs a state signal showing a kind of the liquid flowing in the liquid delivery channel 34 and whether or not the correction can be conducted. The state signal may be substituted by, for example, an open/close signal of the valve.

The state signal has a value of for example, 3 bits, and in case that the value of the state signal is “0” or “1”, it shows a state that the dilute solution is flowing in the liquid delivery channel 34. Among them, the value “0” shows a case that a time period while the dilute solution is flowing is shorter than the predetermined period so that the correction movement is incapable. In other words, the value “0” shows a liquid change period until a certain cleaning chemical is changed to another cleaning chemical. The value “1” shows a case that the time period while the dilute solution is flowing is longer than the predetermined period so that the correction movement is capable. In other words, the value “1” is a drying period (including a delivery period for interchanging the semiconductor substrate) of the semiconductor substrate (B).

Meanwhile, in case that the value of the state signal is “2”˜“4”, it shows a state that the cleaning chemical corresponding to each value is flowing in the liquid delivery channel 34.

A state signal receiving part 442 arranged on the information processing unit 44 receives the above-mentioned state signal. Then a correcting part 443 arranged on the information processing unit 44 judges the value of the state signal. In case that the value is “1”, a measurement value measured by the concentration measuring part 441 is obtained and the obtained value is set as the reference measurement value, and then the concentration measuring part 441 is corrected based on the reference measurement value. In this embodiment, since the dilute solution is the water whose absorbance can be assumed zero, a background compensation (an offset compensation) is conducted based on the reference measurement value.

In accordance with this arrangement, it is possible to provide the concentration measuring device 4 of a simple arrangement as being a fixed cell that can conduct a correction movement without interrupting the semiconductor manufacturing process and that can measure the concentration while the chemical flows.

The present claimed invention is not limited to the above-mentioned embodiment.

For example, the correcting movement may be conducted by flowing the second fluid, for example, during the waiting period of the process or during the delivery period of the substrate. In addition, in the above-mentioned embodiment the correction may be conducted during a period between the spraying process of the cleaning chemical and the succeeding spraying process of the cleaning chemical.

In addition, this invention can be applied to not only the cleaning process but also an etching process or a coating process. In this case, the first fluid is an etching liquid or a coating liquid. A dissolved substance of the first fluid may be a solid or a gaseous body.

Furthermore, the second fluid is not limited to the water, and may be alcohol, in other words, it may be a fluid whose absorbance can be assumed zero or a certain fixed value in a wavelength where a component in the first fluid whose concentration is necessary to be measured is absorbed.

In addition, the first fluid and the second fluid may be a gaseous body.

Furthermore, the offset correcting movement may be that a measured spectrum is corrected based on a broad reference spectrum obtained when the second fluid flows. In addition, not only the offset correction but also a gain correction may be possible depending on a selection of the second fluid. A temperature correction may be conducted by measuring a spectrum change when the temperature is changed by means of for example, a temperature adjusting mechanism while the second fluid flows.

Additionally, a fundamental technical idea of this invention can be applied also to a measurement of physicality other than the concentration of the fluid, for example, a measurement of a refractive index or an electric conductivity.

More specifically, instead of the above-mentioned concentration measuring device 4, may be used a physicality measuring device that measures a physicality such as a refractive index or an electric conductivity of a sample solution (the first fluid or the second fluid) flowing in a flow channel.

In this case, the physicality measuring device comprises a physicality measuring part that measures a physicality of a fluid flowing in the flow channel, and a correcting part that obtains a reference measurement value as being a measurement value measured by the physicality measuring part during a period while the second fluid is judged to flow in the flow channel by a value of the state signal and that corrects the physicality measuring part by the use of the reference measurement value.

As a concrete example in case that the physicality measuring device is the refractive index measuring device that measures the refractive index of the fluid represented are a type (an Abbe's refractometer) that measures an absolute value of the refractive index of the sample fluid and a differential refractometer (a Fresnel type differential refractometer or a polarization type differential refractometer) that measures a difference between the refractive index of the sample fluid and the refractive index of the reference fluid.

Since the refractive index varies in accordance with the concentration of the fluid depending on a kind of the dissolved substance or the solvent, it is possible to use the refractive index measuring device as the concentration measuring device of the sample fluid. In this case, it can be said that the refractive index measuring device substitutes the optical concentration measuring device of the above-mentioned embodiment

As a concrete example in case that the physicality measuring device is the electric conductivity measuring device that measures the electric conductivity of the fluid represented are, for example, of an electrode type and of an electromagnetic induction type. The physicality measuring device of the electrode type measures the electric conductivity by inserting a metal electrode in the sample fluid. A representative example of the physicality measuring device of the electrode type is of an alternating voltage type. Finally, the physicality measuring device conducts the temperature compensation on the sample fluid and measures the electric conductivity that is converted into 25° C. The physicality measuring device of the electromagnetic induction type comprises a primary side coil and a secondary side coil, and it is so configured that the sample fluid penetrates magnetic flux rings made by each coil. When an alternating current flows in the primary side coil, an induction current flows in accordance with the electric conductivity of the sample fluid, and the electric conductivity of the sample fluid is measured by measuring a secondary voltage generating in the secondary side coil in accordance with the induction current.

Since the electric conductivity varies in accordance with the concentration of the fluid depending on the dissolved substance or the solvent, it is possible to use the electric conductivity measuring device as the concentration measuring device of the sample fluid. In this case, it can be said that the electric conductivity measuring device substitutes the optical concentration measuring device of the above-mentioned embodiment

In addition, it is a matter of course that the present claimed invention is not limited to the above-mentioned embodiment and may be variously modified without departing from a spirit of the invention.

1. A concentration measuring device used together with a main body that has a flow channel, that exclusively flows a first fluid used in a manufacturing process and a second fluid whose concentration is known and that is used in the manufacturing process in the flow channel, and that outputs a state signal showing whether or not the fluid flowing in the flow channel is the second fluid, wherein comprising
a concentration measuring part that measures a concentration of a predetermined component in the fluid flowing in the flow channel,
a state signal receiving part that receives the state signal from the main body, and
a correcting part that obtains a reference measurement value as being a measurement value measured by the concentration measuring part during a period while it is judged that the second fluid flows in the flow channel by the state signal and that corrects the concentration measuring part based on the reference measurement value.

2. The concentration measuring device described in claim 1, wherein
the manufacturing process is a semiconductor manufacturing process, and the main body flows the second fluid in the flow channel during at least either one of a semiconductor substrate cleaning period, a semiconductor substrate delivery period, a semiconductor substrate drying period and a waiting period.

3. The concentration measuring device described in claim 1, wherein
the main body comprises a mixing part that mixes introduced one or a plurality of undiluted solutions with the second fluid in a predetermined ratio so as to produce the first fluid and that flows the produced first fluid, and
in case that the second fluid flows in the flow channel, the undiluted solution is halted to be introduced into the mixing part.

4. The concentration measuring device described in claim 3, wherein
the second fluid is a dilute solution and the correcting part conducts an offset compensation as the correction.

5. The concentration measuring device described in claim 1, wherein
the concentration measuring device comprises a transparent cell arranged in the flow channel, a light source that irradiates light on the transparent cell, a light detecting part that receives the light having passed the transparent cell and that outputs a signal whose value depends on intensity of the received light and a concentration measuring part that calculates a concentration of the fluid by providing a predetermined calculation on the value of the detected signal of the light detecting part, and
the correcting part provides a compensation on the calculation.

6. A manufacture processing system comprising
a main body that has a flow channel, that exclusively flows a first fluid used in a manufacturing process and a second fluid whose concentration is known and that is used in the manufacturing process in the flow channel, and that outputs a state signal showing whether or not the fluid flowing in the flow channel is the second fluid, and
a concentration measuring device having a concentration measuring part that measures a concentration of a predetermined component in the fluid flowing in the flow channel, a state signal receiving part that receives the state signal from the main body, and a correcting part that obtains a reference measurement value as being a measurement value measured by the concentration measuring part during a period while it is judged that the second fluid flows in the flow channel by a value of the state signal and that corrects the concentration measuring part based on the reference measurement value.

7. A correcting method, wherein
a first fluid used in a manufacturing process and a second fluid whose concentration is known and that is used in the manufacturing process flow exclusively in an identical flow channel, and a state signal that shows whether the fluid flowing in the flow channel is the second fluid or not is output,
a concentration of the second fluid flowing in the flow channel is measured during a period while it is judged that the second fluid flows in the flow channel by a value of the state signal, and
the concentration measurement is corrected based on a reference measurement value as being the measurement result.

8. The correcting method described in claim 7, wherein
the manufacturing process is a semiconductor manufacturing process, and the second fluid flows in the flow channel during at least either one of a semiconductor substrate cleaning period, a semiconductor substrate delivery period, a semiconductor substrate drying period and a waiting period.
